(19) United States
(12) Patent Application Publication
(10) Pub. No.: US 2025/0052992 A1
(43) Pub. Date: Feb. 13, 2025

(54) MICROSECOND MELTING AND REVITRIFICATION OF CRYO SAMPLES WITH A CORRELATIVE LIGHT ELECTRON MICROSCOPY SETUP

(71) Applicant: ECOLE POLYTECHNIQUE FEDERALE DE LAUSANNE (EPFL), Lausanne (CH)

(72) Inventors: Gabriele BONGIOVANNI, Lausanne (CH); Oliver Florian HARDER, Lausanne (CH); Marcel DRABBELS, Le Mont sur Lausanne (CH); Ulrich J. LORENZ, Lausanne (CH)

(21) Appl. No.: 18/787,412

(22) Filed: Jul. 29, 2024

Related U.S. Application Data
(60) Provisional application No. 63/532,183, filed on Aug. 11, 2023.

(51) Int. Cl. G02B 21/30; G02B 21/06; G02B 21/26; G02B 21/36; H01J 37/22; H01J 37/26

(52) U.S. Cl. CPC G02B 21/30; G02B 21/06; G02B 21/26; G02B 21/367; H01J 37/22; H01J 37/26; H01J 2237/204

(57) ABSTRACT

An apparatus for observing dynamic systems by time-resolved microscopy has an optical microscope including a cryo stage for receiving a cryo sample and maintaining the cryo sample at a cryogenic temperature, a heating system configured to temporarily heat at least a portion of the cryo sample such that the portion of the cryo sample melts to a liquid state, temporarily resides in the liquid state, and then revitrifies, and an image detector associated with the optical microscope for detecting magnified images of the cryo sample generated by the optical microscope. Detected images may be recorded and analyzed to inform on-the-fly adjustment of heating power level delivered to the cryo sample. In a correlative light-electron microscopy method, the revitrified cryo sample is observed using an electron microscope.

### CROSS-REFERENCE TO RELATED APPLICATION

The present application claims priority and benefit of U.S. Provisional Patent Application No. 63/532,183 filed Aug. 11, 2023, the entire disclosure of which is incorporated herein by reference.

### FIELD OF THE DISCLOSURE

The present disclosure relates to time-resolved cryo-electron microscopy (cryo-EM) for studying dynamics of extremely fast dynamic systems such as protein systems, biological systems, inorganic chemical systems, and the like, and to an apparatus and method for melting and revitrification of cryo samples in furtherance of other research benefits related to cryo samples.

### BACKGROUND OF THE DISCLOSURE

Structure determination of proteins has made rapid progress in the last decade, particularly due to resolution improvements in cryo-EM, which is becoming a preferred method in structural biology, and the advent of machine learning approaches for protein structure prediction. However, these advances expose an incomplete understanding of the dynamics and the function of proteins. Understanding and ultimately predicting protein function is an ongoing goal in structural biology.

The incomplete understanding of protein dynamics and function is to a large extent a consequence of the difficulties in observing proteins as they perform their tasks. Observing protein dynamics requires not only near-atomic spatial resolution, but also a time resolution that is sufficient to observe the domain motions that are frequently associated with the activity of a protein and that typically occur on very short timescales of microseconds to milliseconds. Time-resolved cryo-EM has enabled observations of a range of processes. Typically, dynamics are initiated by rapidly mixing two reactants and spraying them onto a specimen grid, which is then rapidly plunge frozen to trap short-lived intermediates. However, the time resolution of this method is fundamentally limited by the time required for plunge freezing, which is on the order of one millisecond, too slow to observe many relevant dynamics.

Inventors herein have recently introduced a novel approach to time resolved cryo-EM that affords microsecond time resolution. This is notably fast enough to enable the observation of many domain motions. The approach employs a laser beam to locally melt a cryo sample for several tens of microseconds, providing a well-defined time window during which the proteins can undergo conformational motions in liquid. A range of stimuli may be used to initiate specific dynamics. For example, caged compounds can be used to release ATP, ions, small peptides, or induce a pH change. As the dynamics of the particles unfold, the heating laser is switched off, so that the cryo sample rapidly cools and revitrifies, arresting the particles in their transient configurations.

The viability of this approach, and the spatial and temporal resolution it affords, have been demonstrated. Proof-of-principle experiments confirm that once the sample is laser melted, particles can undergo motions in liquid and that upon revitrification, the particles are trapped in their transient states with microsecond time resolution. The success of a revitrification experiment may be assessed “on-the-fly” (i.e., as the experiment is proceeding). In a successful experiment, the revitrified area in the center of the laser focus is surrounded by a region in which the sample has crystallized since its temperature has not exceeded the melting point. By adjusting the laser power to keep the diameter of the revitrified area constant, one may ensure that in each experiment, the sample undergoes substantially the same temperature evolution. That the melting and revitrification process leaves the proteins intact has also been demonstrated. Near-atomic resolution reconstructions may be obtained from revitrified cryo samples, suggesting that the revitrification process does not fundamentally limit the obtainable spatial resolution. The approach is now starting to be used to study the fast dynamics of a variety of systems.

By enabling atomic-resolution observations of the microsecond dynamics of proteins, the new method may fundamentally advance understanding of protein dynamics and function. However, for the method to achieve this goal, it is crucial to make the method easily accessible so that a large number of groups can adopt it. Currently, melting and revitrification experiments are performed in situ, using a transmission electron microscope that has been modified for time-resolved experiments. Modification of the transmission electron microscope involves mounting a laser system having two laser sources onto the microscope, and arranging mirrors within the electron microscope to direct the respective laser beams. A first laser source emits a pulsed light beam which is directed onto a region of the cryo sample by a mirror mounted above an upper pole piece of the microscope's objective lens to cause the cryo sample region to melt and revitrify in a time resolved manner. A second laser source emits another pulsed light beam to illuminate an emitter of the microscope's Schottky field emission gun (FEG) in order to generate photoelectron pulses. The FEG emitter is illuminated by directing the second laser beam through a viewport on a side of the microscope's FEG that ordinarily serves for electron beam monitoring purposes. The laser beam enters the emitter assembly through a hole in an electrostatic focusing lens, and is reflected by a mirror to impinge on the tip of the Schottky emitter at a slight angle with respect to the electron beam axis. Alternatively, the second laser beam may be directed at the extractor of the FEG.

Setting up and testing such a transmission electron microscope, which few labs have at their disposal, presents a significant impediment to widespread adoption of the new technique. Therefore, a more accessible and technically less involved solution is desired.

Furthermore, during the in situ experiments summarized above, the sample must be exposed to a small electron dose in order to locate and center areas for revitrification at low magnification. This is significant because the exposure to a dose of only a few electrons per Ångstrom squared can induce so much fragmentation that the proteins will completely unravel once the sample is melted. Therefore, it is sensible to avoid exposure even to the small dose required for low-magnification imaging, which may potentially cause some proteins to lose their function even though no structural damage is evident.

### SUMMARY OF THE DISCLOSURE

The present disclosure describes an apparatus that uses an optical (i.e., light) microscope in combination with one or more light sources, for example laser sources, for melting and revitrification that is technically much simpler than the known apparatus and completely avoids electron beam exposure prior to melting and revitrification, thus eliminating any damage to the observed particles. Using an optical microscope apparatus for revitrification may also enable new types of experiments. The simple optical layout of the apparatus makes it easier to combine different light beams and wavelengths, which can be used to trigger different types of experiments.

A major challenge in developing the apparatus was using an optical microscope to assess the success of an experiment on-the-fly. This challenge is met by analyzing difference images obtained by subtracting an image recorded before revitrification from a subsequent image recorded after revitrification to check for a characteristic pattern. This pattern may be attributed to the phase behavior of water after light irradiation. Understanding this phase behavior is not straightforward even for experts in the field of cryo-electron microscopy.

The new optical melting and revitrification apparatus may be used in conjunction with an unmodified cryo-electron microscope to perform correlative light-electron microscopy investigations of cryo samples.

### BRIEF DESCRIPTION OF THE DRAWING VIEWS

The nature and mode of operation of the present disclosure will now be more fully described in the following detailed description taken with the accompanying drawing figures, in which:

FIG. 1 is a schematic view illustrating an apparatus for observing dynamic systems by time-resolved microscopy according to an embodiment of the present disclosure;

FIG. 2 is a schematic view illustrating a cryo stage and cryo sample of the apparatus shown in FIG. 1;

FIG. 3 is schematic view illustrating an apparatus for observing dynamic systems by time-resolved microscopy according to another embodiment of the present disclosure;

FIG. 4 is schematic view illustrating an apparatus for observing dynamic systems by time-resolved microscopy according to a further embodiment of the present disclosure;

FIG. 5 is a flow diagram illustrating control logic for “on-the-fly” adjustment of laser power according to an aspect of the present disclosure;

FIG. 6A is an optical micrograph of a sample grid of a cryo sample recorded before melting and revitrification;

FIG. 6B is a difference image of the cryo sample shown in FIG. 6A obtained by subtracting the image of FIG. 6A from a corresponding image of the cryo sample recorded after melting and revitrification, wherein laser power is within a suitable range;

FIG. 7A is another optical micrograph of a sample grid of a cryo sample recorded before melting and revitrification;

FIG. 7B is a difference image of the cryo sample shown in FIG. 7A obtained by subtracting the image of FIG. 7A from a corresponding image of the cryo sample recorded after melting and revitrification, wherein laser power is insufficient;

FIG. 8A is another optical micrograph of a sample grid of a cryo sample recorded before melting and revitrification;

FIG. 8B is a difference image of the cryo sample shown in FIG. 8A obtained by subtracting the image of FIG. 8A from a corresponding image of the cryo sample recorded after melting and revitrification, wherein laser power is excessive; and

FIG. 9 is a flow diagram illustrating a correlative light-electron microscope method according to a further embodiment of the present disclosure.

### DETAILED DESCRIPTION OF THE DISCLOSURE

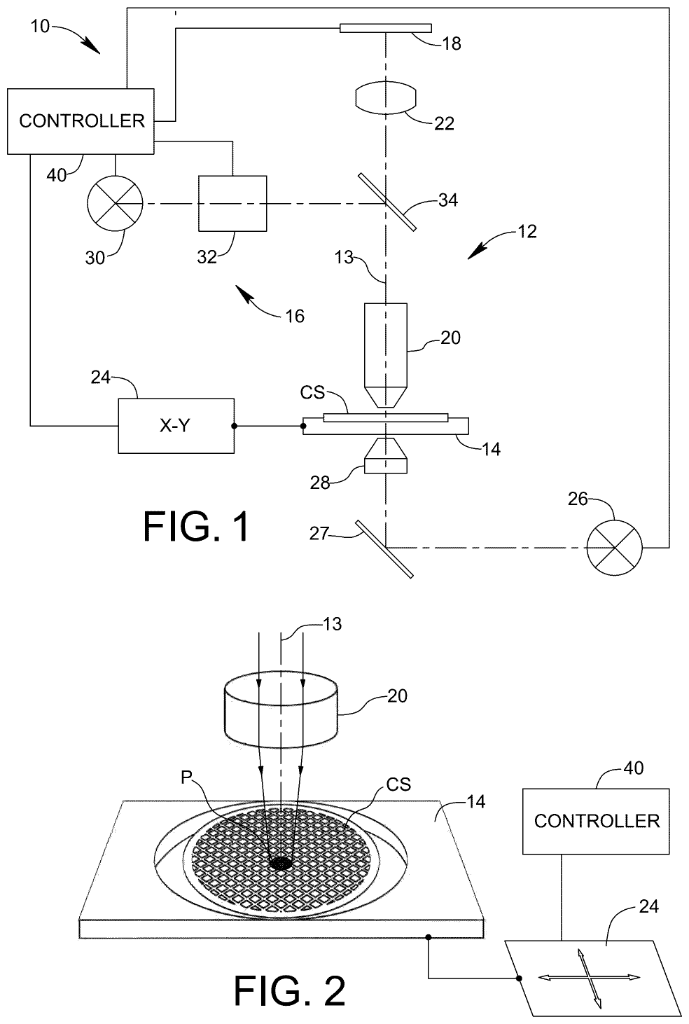

FIGS. 1-2 schematically show an apparatus 10 according to an embodiment of the present disclosure useful for microscopic observation and study of dynamic systems in which changes occur in microsecond time frames. Apparatus 10 is operable to conduct time resolved microscopic investigations with microsecond time resolution without the need for complex modification of an electron microscope.

Apparatus 10 may generally comprise an optical (i.e., light) microscope 12 including a cryo stage 14 for receiving a cryo sample CS and maintaining the cryo sample CS at a cryogenic temperature, a heating system 16 operable to temporarily heat at least a portion P of the cryo sample CS, and an image detector 18 associated with the optical microscope 12 for detecting magnified images of portion P of cryo sample CS generated by the optical microscope.

In addition to cryo stage 14, optical microscope 12 may include an optical axis 13 intersecting cryo stage 14 normal to a plane of the cryo stage, and an objective lens 20 located on optical axis 13 in an optical path between cryo stage 14 and image detector 18. Optical microscope 12 is shown as also including tube optics 22 in the optical path between objective lens 20 and image detector 18 for imaging magnified images of cryo sample CS including portion P onto an image plane of image detector 18.

FIG. 2 illustrates cryo stage 14 and cryo sample CS in greater detail. Cryo stage 14 is adapted to receive and support cryo sample CS and maintain the cryo sample at a cryogenic temperature within a range from −150° C. to −273° C. (absolute zero), preferably at a temperature below the temperature at which nitrogen becomes a liquid (−195.8° C.). Cryo stage 14 may be cooled using liquid nitrogen, and the condensation of water vapor may be avoided by enclosing a volume around cryo sample CS so that ambient air can only enter the enclosed volume through small gaps around objective lens 20. Ambient air in the enclosed volume may be displaced by the evaporating liquid nitrogen, such that contamination of cryo sample CS is kept to a minimum and condensation of water vapor is prevented. Cryo stage 14 may be movable in a plane orthogonal to optical path 13 by an X-Y carriage mechanism 24 of optical microscope 12.

By way of non-limiting example, cryo sample CS may be prepared on an UltrAuFoil R1.2/1.3 300 mesh gold grid available from Quantifoil Micro Tools GmbH, which may be rendered hydrophilic through plasma cleaning for one minute using a PELCO easiGlow discharge cleaning system available from Ted Pella, Inc. set at negative polarity with a plasma current of 0.8 mA and a residual air pressure of 0.2 mbar. A volume of 3 μl of a sample solution (e.g., mouse heavy chain apoferritin, 8.5 mg/ml in 20 mM HEPES buffer with 300 mM sodium chloride at pH 7.5) may be applied to the specimen grid, which may then be plunge-frozen using a Vitrobot Mark IV system from Thermo Fisher Scientific, with 3 second blotting time, 95% relative humidity at a temperature of 10 C. Cryo sample CS may be screened on a JEM-2200FS field emission electron microscope from JEOL Ltd. before revitrifying the cryo sample using optical microscope apparatus 10. As will be understood by persons skilled in the art, other cryo sample types and preparation protocols may be used.

Optical microscope 12 may further include a bright field illumination system having an illumination source 26, and optical element 27 such as a prism or mirror for redirecting light from illumination source 26 along optical path 13, and a focusing lens 28 on optical path 13 beneath cryo stage 14 for illuminating cryo sample CS with bright field illumination from below.

In one embodiment, optical microscope 12 may be a Leica DM6000 CFS Confocal Fixed Stage System available from Leica Microsystems that is equipped with a Linkam CMS196 cryo stage for correlative microscopy as cryo stage 14. Of course, other commercially available optical microscopes and cryo stages may be used as optical microscope 12 and cryo stage 14.

Heating system 16 is configured to temporarily heat at least portion P of cryo sample CS such that portion P melts to a liquid state, resides in the liquid state for a brief time period, and revitrifies by heat transfer to the unmelted portion of the cryo sample surrounding portion P after the temporary heating has ceased. For example, portion P may reside in a liquid state for several tens of microseconds. Heating system 16 may include at least one illumination source 30, a pulse modulator 32 associated with illumination source 30, and an optical element 34.

Illumination source 30 may be, for example, a continuous wave laser emitting a continuous light beam at a predetermined wavelength. For example, illumination source 30 may be embodied by a Ventus 532 laser emitting light at a wavelength of 532 nm. Other laser sources having the same emission wavelength or different emission wavelengths may be used. Non-laser light sources emitting light in broader wavelength bands may also be used.

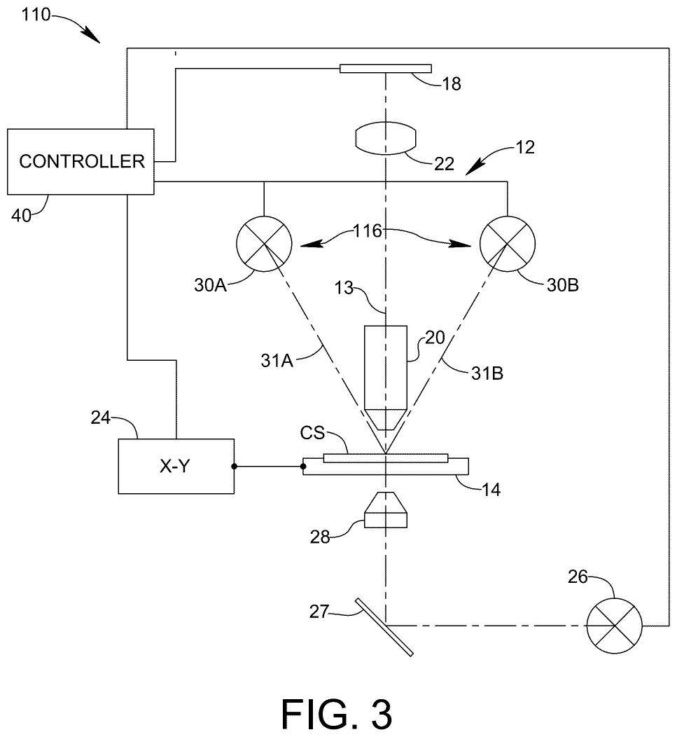

In the embodiment shown in FIG. 1 wherein illumination source 30 emits a continuous beam, pulse modulator 32 operates to chop the continuous beam to provide at least one brief light pulse having a predetermined duration. The predetermined duration may be in a range of a few nanoseconds up to about 10 milliseconds. In one example embodiment, the predetermined duration is about 40 microseconds. To achieve time resolution in a nanosecond range, a different grid geometry for supporting cryo sample CS that allows for faster heat transfer may be provided. In this case, pulses of light lasting from a few nanoseconds up to a microsecond may be used. Pulse modulator 32 may take the form of an acousto-optic modulator, a Pockels cell, a very fast mechanical shutter that briefly unblocks the beam, or another device for creating a brief pulse in the mentioned range of duration. For example, a suitable acousto-optic modulator is available from AA Opto Electronic of Orsay, France. As will be described below in connection with another embodiment shown in FIG. 3, illumination source 30 may be a laser source configured to emit laser pulses each of a predetermined duration in the mentioned pulse duration range instead of emitting a continuous beam, in which case pulse modulator 32 may be omitted.

Optical element 34 may be positioned at a location along optical axis 13 between objective lens 20 and tube optics 22 for redirecting a light beam from illumination source 30 (or a portion of such light beam) along optical axis 13 toward cryo sample CS. Optical element 34 may be a dichroic mirror, a semi-transparent mirror, a polarizer, a mirror having a central aperture, or a movable mirror mounted for selective positioning on optical axis 13, for example by rotation about a pivot axis or by simple translation. Providing a dichroic mirror as optical element 34 has the advantage that the dichroic mirror may be selected to reflect light only in a predetermined wavelength band corresponding to the wavelength of light emitted by illumination source 30, and to transmit other wavelengths of light such that light travelling along optical axis from cryo sample 13 toward image detector 18 is not blocked or significantly attenuated before reaching the image detector 18 if the optical element 34 is located between cryo-stage 14 and the image detector. Embodying optical element 34 as a dichroic mirror, a semi-transparent mirror, a polarizer, or a mirror having an aperture eliminates the need to move optical element 34 into and out of optical axis 13, thereby mechanically simplifying apparatus 10.

Image detector 18 may be a light-sensitive pixel-based device such as a complementary metal-oxide semiconductor (CMOS) device or a charge-coupled device (CCD). For example, a Teledyne FLIR Grasshopper 3 camera using CMOS technology has been found suitable for practicing the present disclosure.

Apparatus 10 may further comprise a controller 40 connected to image detector 18, X-Y carriage mechanism 24, illumination source 26, illumination source 30, and pulse modulator 32. For example, controller 40 may be a personal computer or dedicated computer control module configured to send command signals to illumination source 30 and pulse modulator 32 to trigger a light pulse to temporarily heat portion P of cryo sample CS. Controller 40 may also be configured to receive user-inputted positioning instructions and issue corresponding commands to X-Y carriage mechanism to shift cryo stage 14 and cryo sample CS relative to optical axis 13 to bring a different area or region of cryo sample CS within the field of view of optical microscope 12. Controller 40 may also be configured to receive electronic image signals from image detector 18 compute difference images as described below. Controller 40 may include one or more memory modules and one or more processors for executing programming instructions (i.e., software or firmware) stored in the memory modules. Controller 40 may also integrate control functions for operating components of optical microscope 12, for example illumination, focusing, cryo stage positioning, and other functions.

In an aspect of the present disclosure, a first portion of cryo sample CS may be melted and revitrified as described above, cryo stage 14 may be repositioned by X-Y carriage mechanism, and then a second portion of the cryo sample CS may be melted and revitrified, and so on.

FIG. 3 schematically shows an apparatus 110 according to another embodiment of the present disclosure for conducting time resolved microscopic investigations with microsecond or better time resolution. Apparatus 110 is similar to apparatus 10 described above in that it comprises an optical microscope 12, a heating system 116, and an image detector 18. However, apparatus 110 illustrates possible structural variants.

In the embodiment of FIG. 3, optical microscope 12 includes cryo stage 14, objective 20, and tube optics 22 in an optical path from cryo sample CS to image detector 18. Optical microscope 12 of FIG. 3 also includes X-Y carriage mechanism 24 for displacement of cryo stage 14 in a plane orthogonal to optical axis 13.

Heating system 116 includes a plurality of illumination sources 30A and 30B each emitting light at a unique respective wavelength band different from the emitted light wavelength band of the other illumination source. Illumination sources 30A and 30B may be arranged to direct light along respective beam axes 31A and 31B at an angle to main optical axis 13 of optical microscope 12 onto cryo sample CS. In the illustrated embodiment, the beams from illumination sources 30A and 30B may illuminate the entire cryo sample CS, either each individually or in combination with one another. Alternatively, respective focusing optics (not shown) may be provided along beam axes 31A and 31B to concentrate beam energy onto a desired portion of cryo sample CS. In the present embodiment, illumination sources 30A and 30B may be diode lasers wherein the diode drive current is pulsed in order to produce very brief pulses, or they may be diode-pumped lasers configured to emit brief pulses, wherein the pulses have a duration on the order of tens of microseconds. Accordingly, a pulse modulator separate from each illumination source 30A, 30B is omitted in the embodiment of FIG. 3.

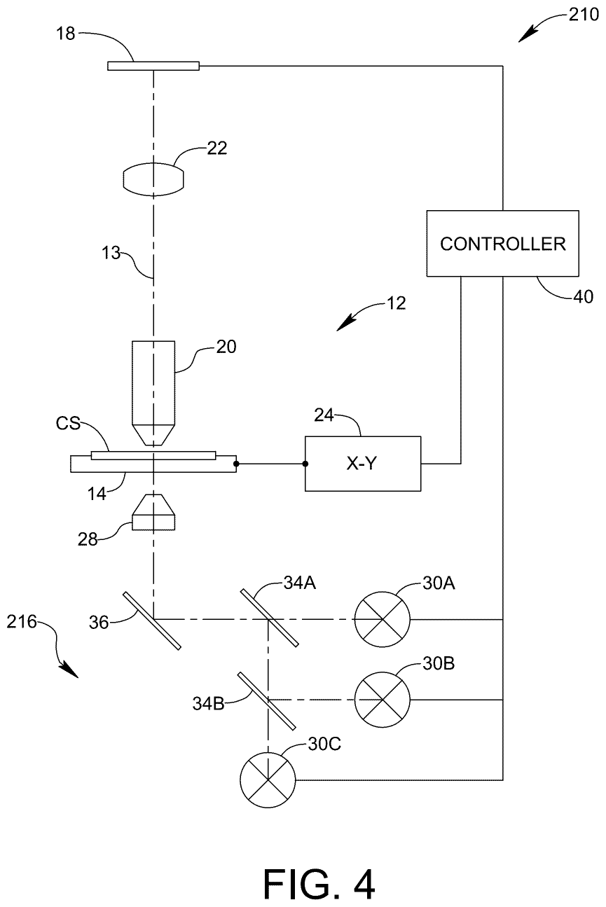

FIG. 4 schematically shows an apparatus 210 according to a further embodiment of the present disclosure for conducting time resolved microscopic investigations with microsecond or better time resolution. Apparatus 210 is similar to apparatus 10 and apparatus 110 described above in that it comprises an optical microscope 12, a heating system 216, and an image detector 18. Apparatus 210 illustrates further structural variants that are possible according to the present disclosure.

In the embodiment of FIG. 4, optical microscope 12 includes cryo stage 14, objective 20, and tube optics 22 in an optical path from cryo sample CS to image detector 18. Optical microscope 12 of FIG. 4 also includes X-Y carriage mechanism 24 for displacement of cryo stage 14 in a plane orthogonal to optical axis 13. Heating system 216 is arranged on a side of cryo stage 14 opposite optical microscope 12, and includes a plurality of illumination sources 30A, 30B, and 30C each emitting light at unique respective wavelength band different from the emitted light wavelength band of the other illumination sources. An optical element 34A is arranged to receive light from first illumination source 30A. Optical element 34A may be a dichroic mirror selected to transmit light from first illumination source 30A through to an optical element 36, and reflect light from second illumination source 30B and third illumination source 30C to optical element 36. An optical element 34B is arranged to receive light from second illumination source 30B and third illumination source 30C. Optical element 34B may be a dichroic mirror selected to reflect light from second illumination source 30B and transmit light from third illumination source 30C. Thus, light from each illumination source 30A, 30B, 30C is directed to optical element 36. Illumination sources 30A, 30B, and 30C may be controlled to provide any one selected uncombined light beam to optical element 36 (i.e., a beam from illumination source 30A, a beam from illumination source 30B, or a beam from illumination source 30C). In addition, illumination sources 30A, 30B, and 30C may be controlled to provide any combination of their respective light beams (i.e., a combined beam from illumination sources 30A and 30B, a combined beam from illumination sources 30A and 30C, a combined beam from illumination sources 30B and 30C, or a combined beam from illumination sources 30A, 30B, and 30C). Beam-combining optical element 34A and/or beam-combining optical element 34B may be a polarizer or a semi-transparent mirror instead of a dichroic mirror.

Optical element 36 is configured and arranged to direct the light it receives along optical axis 13 toward cryo stage 14 and cryo sample CS. Optical element 36 may be, for example, a mirror or a prism. A focusing lens 28 may be provided before cryo stage 14 for focusing the heating beam on a portion of cryo sample CS.

In apparatus 210, illumination sources 30A, 30B, 30C are embodied as diode lasers configured to emit brief pulses on the order of tens of microseconds without the need for a separate pulse modulator, however illumination sources 30A, 30B, and/or 30C may be embodied as continuous lasers or non-laser light sources that emit a continuous beam and have a pulse modulator associated therewith as described with regard to apparatus 10 of the first embodiment.

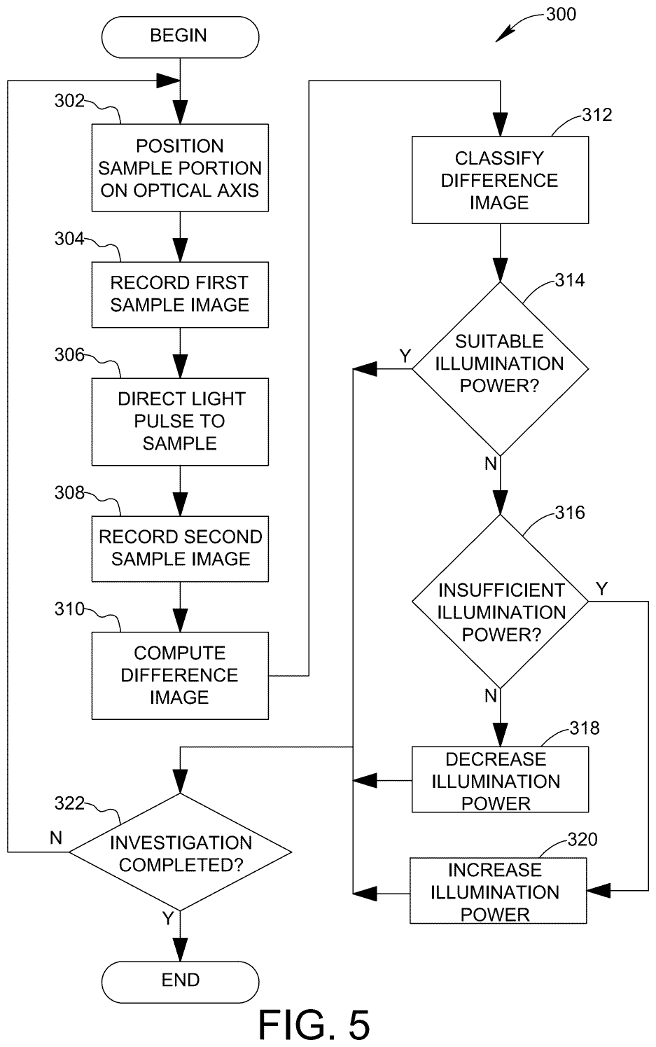

FIG. 5 is a flow diagram illustrating control logic of a method 300 for adjusting illumination power applied by the heating system 16, 116, 216 according to an aspect of the present disclosure. Applicant has found that a difference image computed by subtracting a first image of the cryo sample recorded before melting and revitrification from a second image of the cryo sample recorded after melting and revitrification may reveal features indicating whether the applied illumination power is suitable, insufficient, or excessive for observation of protein dynamics. If the applied illumination power is considered insufficient, it may be increased. Conversely, if the applied illumination power is considered excessive, it may be decreased. Method 300 enables illumination power to be adjusted “on-the-fly” (i.e., as the experimental investigation proceeds) to help assure that meaningful results are recorded.

Method 300 begins at steps 302 and 304 by positioning cryo sample CS on optical axis 13 such that a desired region of the cryo sample is in a field of view of optical microscope 12, and recording a first image of the cryo sample using image detector 18. After the first sample image is recorded, the illumination source 30 (or a combination of illumination sources 30A, 30B, 30C) is/are energized at a first power setting to temporarily heat a portion of the cryo sample according to step 306 such that the portion of the cryo sample in the field of view melts to a liquid state and revitrifies. After the portion of the cryo sample revitrifies, a second image of the cryo sample is recorded pursuant to step 308 using image detector 18. The next step 310 is computing a difference image of the cryo sample by subtracting the first image from the second image (i.e., pixel values from the first image are subtracted from pixel values of the second image to compute the difference image).

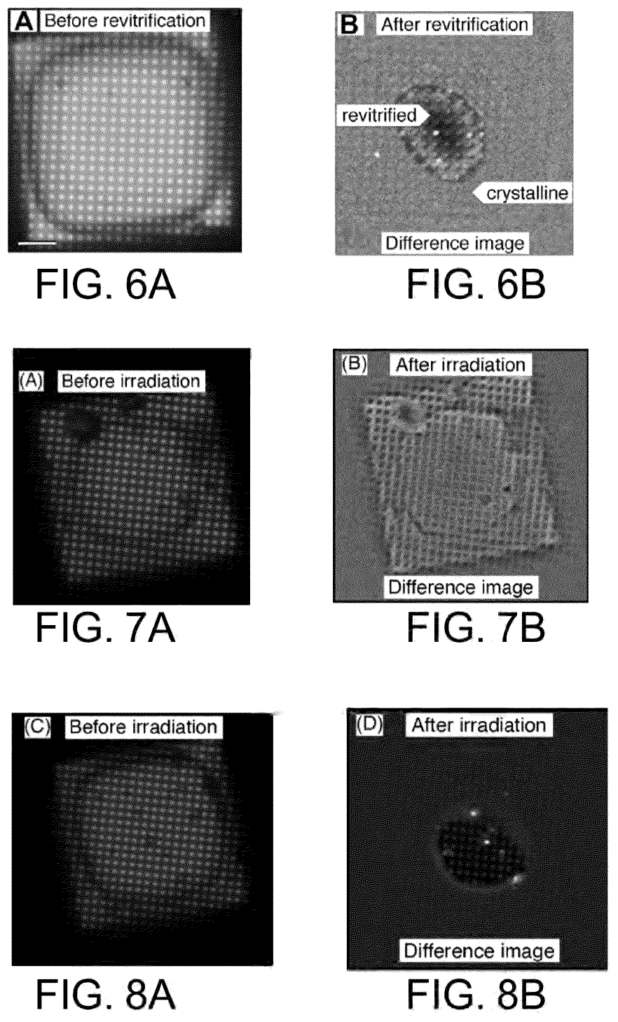

By way of non-limiting example and purely for sake of illustration, reference is made to FIGS. 6A, 6B, 7A, 7B, 8A, and 8B showing a first image and a corresponding difference image when the applied illumination power is suitable (FIGS. 6A and 6B), when the applied illumination power is insufficient (FIGS. 7A and 7B), and when the applied illumination power is excessive (FIGS. 8A and 8B). The images in FIGS. 6A and 6B correspond to a successful melting a revitrification experiment. In the difference image of FIG. 6B, a characteristic signature of successful melting and revitrification is readily apparent. The revitrified area in the center of the grid square is surrounded by a thin, dark ring and features a dark patch in its center. The outline ring is believed to be caused by the formation of crystals in the surrounding area. The dark patch in the center indicates thinning of the cryo sample due to evaporation.

The images in FIGS. 7A and 7B correspond to an unsuccessful revitrification experiment in which applied illumination power was insufficient. The difference image of FIG. 7B does not exhibit the characteristic contrast changes associated with successful melting and revitrification that can be seen in FIG. 6B. Most features in the difference image of FIG. 7B correspond to structures visible in the first image of FIG. 7A recorded before light irradiation, and therefore likely arise from a change in defocus due to a deformation of the specimen grid under light irradiation.

The images in FIGS. 8A and 8B correspond to an unsuccessful revitrification experiment in which applied illumination power was excessive. The sample evaporates in the center of the grid square, which leads to strong contrast changes in the difference image, wherein the holey gold film appears dark in the evaporated area, and the holes appear bright.

Returning now to FIG. 5, method 300 continues at step 312 by analyzing the difference image and classifying the difference image into one of three classes: suitable illumination power, insufficient illumination power, or excessive illumination power. If the difference image exhibits a pattern of features most consistent with a suitable illumination power level, it is assigned the suitable illumination power classification. If the difference image exhibits a pattern of features most consistent with an insufficient illumination power level, it is assigned the insufficient illumination power classification. If the difference image exhibits a pattern of features most consistent with an excessive illumination power level, it is assigned the excessive illumination power classification. The classification step may be performed automatically using automated image processing and evaluation techniques and algorithms to identify features in the difference image. Additionally or alternatively, the classification step may be performed automatically using a classification module trained by machine learning using a data set of training difference images in the suitable, insufficient, and excessive illumination power classifications such that the classification module is qualified to assign each new difference image to the appropriate classification.

If the difference image is assigned to the suitable illumination power classification, then the current illumination power is maintained and decision step 314 directs flow to decision step 322. If not, and instead the difference image is assigned to the insufficient illumination power classification, then decision block 316 directs flow to step 320 in which illumination power is increased. Otherwise, the difference image is assigned to the excessive illumination power classification, and decision block 316 directs flow to step 318 in which illumination power is decreased. The amount of the illumination power decrease in step 318, and the amount of illumination power increase in step 320, may be a variable amount that is based on the appearance of the difference image, or it may be a predetermined incremental amount. Upon completion of power decrease step 318, flow is directed to decision step 322. Likewise, upon completion of power increase step 320, flow is directed to decision step 322.

Decision step 322 determines if the investigation is completed. If so, method 300 comes to an end. If not, and there are other portions or regions of the cryo sample to be investigated, then flow returns to step 302 to reposition the cryo sample relative to optical axis 13 so that another desired region of cryo sample CS is in the field of view of optical microscope 12.

Melting and revitrification with an optical microscope according to the present disclosure is in several respects complementary to the known in situ approach using an electron microscope, with each approach offering distinct advantages and insights. It is usually more straightforward to determine the diameter of the revitrified area in an in situ experiment because the surrounding crystalline region offers a strong contrast in an electron microscope, whereas it may be more difficult to detect in optical difference images if the crystallites are too small. In situ experiments also offer the advantage that the behavior of the particles during revitrification can be assessed immediately, either by visual inspection or from an on-the-fly reconstruction, so that the illumination parameters can be adjusted as needed. Moreover, in situ experiments will likely remain important to further characterize and advance the experimental revitrification approach. For example, in situ experiments inform understanding of partial crystallization and phase behavior of cryo samples during rapid heating. Finally, controlling the plateau temperature that the cryo sample reaches during a light pulse is somewhat easier for in situ experiments, where evaporative cooling in the vacuum of the electron microscope can be used to provide a negative feedback that limits the sample temperature at high illumination powers. In revitrifcation experiments with the optical microscope, this feedback effect may be much reduced due to the lower evaporation rate of water at ambient pressure.

A correlative revitrification approach using an optical microscope apparatus for melting and revitrification of a cryo sample followed by investigation of the cryo sample by electron microscopy according to an aspect of the present disclosure offers the significant advantage that its implementation is technically less involved, thereby facilitating more widespread research exploring the fast dynamics of a variety of systems. Once suitable experimental conditions for a time-resolved experiment have been established, cryo samples for high-resolution imaging can be most conveniently revitrified with an optical microscope apparatus of the present disclosure. Imaging the cryo sample with the optical microscope apparatus also does not damage the particles, in contrast to in situ experiments with an electron microscope, where the cryo sample must be exposed to a small electron dose in order to locate and center areas for revitrification at low magnification. This is significant because exposure of the cryo sample to a dose of only a few electrons/Å² induces so much fragmentation that the proteins may completely unravel once the cryo sample is melted. It is therefore sensible to avoid exposure even to the small dose required for low-magnification imaging, which may potentially cause some proteins to lose their function even though no structural damage is evident.

Using an optical microscope apparatus for revitrification may also enable new types of experiments. The simple optical layout of the apparatus makes it straightforward to combine different light beams and wavelengths, which may be used to trigger different dynamics or monitor the revitrification process. For example, a separate ultraviolet laser beam may be used to release a caged compound in selected grid squares of a cryo sample, such as caged ATP, ions, or even peptides. With the sample still in its vitreous state, the proteins are unable to react to this change in their chemical environment. However, once the cryo sample is laser melted, the compound becomes available to initiate conformational dynamics. By releasing different quantities of the caged compound in different grid squares of a cryo sample, it is possible to study how the concentration of the compound affects the dynamics, with all experiments conducted on the very same specimen grid, thus guaranteeing the most reproducible conditions. It will also become possible to combine revitrification experiments with other types of correlative microscopy. It is even conceivable to perform experiments on entire cells, as long the heat transfer in the cryo sample can be engineered to be fast enough, so that vitrification can be achieved after the end of the illumination pulse. Finally, the disclosed optical microscope apparatus may also provide a practical approach to improve the quality of conventional cryo samples. Melting and revitrification may be used to turn some crystalline areas vitreous or reduce the ice thickness through evaporation. It may also be possible to reduce beam induced specimen motion by releasing stress in the vitreous ice film through irradiation with a sequence of laser pulses.

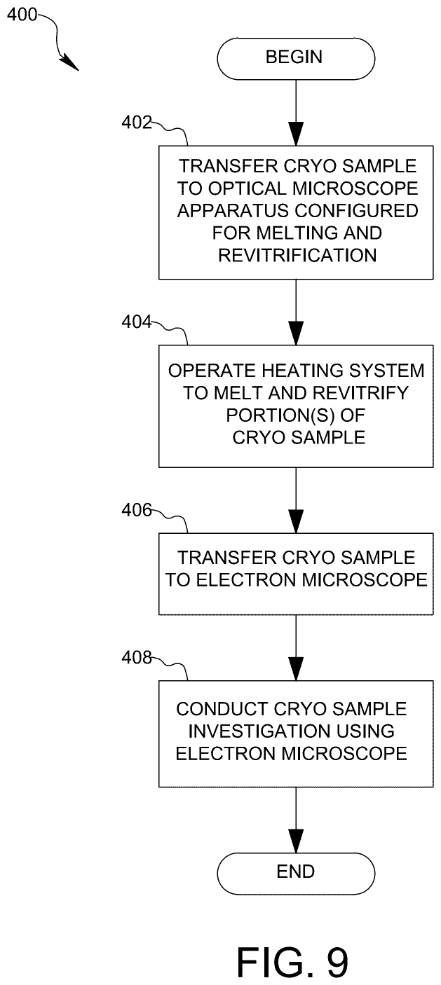

FIG. 9 illustrates a correlative light-electron microscopy method 400 according to an embodiment of the present disclosure. In step 402 of the method, a cryo sample is transferred to an optical microscope apparatus configured for melting and revitrification, for example apparatus 10, 110, or 210 of the present disclosure. Melting and revitrification of at least a portion of the cryo sample is carried out in step 404 using the optical microscope apparatus as described above. Optical microscope images (i.e., optical micrographs) of the cryo sample may be obtained before and after melting and revitrification during step 404. More than one area or region of the cryo sample may be melted and revitrified during step 404. The cryo sample is then transferred to an electron microscope in step 406, and the cryo sample is further investigated by means of the electron microscope pursuant to step 408. One or more electron microscope images (i.e., electron micrographs) of the cryo sample may be obtained during step 408. As will be appreciated, the optical micrographs obtained in step 404, and the electron micrographs obtained in step 408, enable researchers to study the dynamics of the observed cryo sample at time resolution intervals on the order of tens of microseconds or shorter.

The following describes an example of method 400 conducted by applicant.

Cryo samples were prepared on UltrAuFoil R1.2/1.3 300 mesh grids (source: Quantifoil), which were rendered hydrophilic through plasma cleaning for one minute using a Tedpella “Easy glow” discharge system, negative polarity with a plasma current of 0.8 mA and a residual air pressure of 0.2 mbar. A volume of 3 μl of sample solution (mouse heavy chain apoferritin, 8.5 mg/ml in 20 mM HEPES buffer with 300 mM sodium chloride at pH 7.5) was applied to the specimen grid, which was then plunge-frozen with a Vitrobot Mark IV (source: Thermo Fisher Scientific), using three second blotting time, 95% relative humidity at a temperature of 10° C. The grids were screened on a JEM-2200FS electron microscope (source: JEOL Ltd., Japan) before revitrifying them in the optical microscope apparatus.

Revitrification experiments were performed with a modified Leica DM6000 CFS confocal fixed stage optical microscope system (source: Leica Microsystems) equipped with a Linkam CMS 196 cryo stage (source: Linkam Scientific). Laser pulses for melting and revitrification were obtained by chopping the output of a Ventus 532 continuous wave laser (source: Novanta Photonics) emitting a 532 nm wavelength beam with an acousto-optic modulator (source: AA Opto Electronic, France). The pulsed beam was focused to a spot size of 25 μm FWHM (full width at half maximum) in the sample plane, as determined from an image of the beam recorded with a CCD camera placed in the sample location. Optical bright field images were recorded with a Grasshopper3 camera (source: Teledyne FLIR). Difference images for assessing the success of the revitrification experiments were obtained by subtracting an image of the sample before laser irradiation from an image recorded after laser irradiation. The before and after images were acquired as averages of 15 exposures each (1 s), which were aligned using phase correlation-based image registration.

The cryo samples were transferred to the JEM-2200FS electron microscope and electron micrographs of some of the revitrified areas were recorded. Resultant images were obtained by stitching together several electron micrographs acquired at higher magnification, in which crystalline areas of the cryo sample could be more readily identified. This step was performed to correlate the optical micrographs of these areas with electron micrographs to assist the inventors in interpreting the features observed in the optical micrographs, and is merely an optional step that may be added to method 400, not a required step.

The cryo samples were then transferred to a high-resolution transmission electron microscope for single-particle imaging, in this example a Titan Krios G4 cryo-transmission electron microscope (source: Thermo Fisher Scientific). Of course, if the step described in the previous paragraph is omitted, then the cryo samples may be transferred directly from apparatus 10, 11, 210 to the high-resolution transmission electron microscope.

Electron micrographs for single-particle reconstructions were acquired by operating the Titan Krios G4 electron microscope at 300 kV accelerating voltage and using a 10 eV slit width provided by a Selectris X energy filter (source: Thermo Fisher Scientific). The electron micrographs were recorded with a Falcon 4 camera (source: Thermo Fisher Scientific), with an exposure time of about 2.5 s and a total dose of 50 electrons Å². The pixel size was 0.455 Å, and defocus values were in the range of 0.9-1 μm.

Single-particle reconstructions were performed using CryoSPARC v.3.3.2 software (source: Structura Biotechnology Inc.). Briefly, the conventional (revitrified) apoferritin dataset comprises 10145 (12047) images. Patch motion correction and CTF estimation yielded 6242 (3671) images with a resolution better than 6 Å, which were kept for further processing. Using template based particle picking, 2937383 (1714924) particles were identified. Following two rounds of 2D classification, 534606 (212377) particles were retained for ab initio reconstruction (C1 symmetry), followed by heterogeneous refinement (O symmetry) using three classes. After reextraction, the 447704 (95786) particles found in the most populated classes were then used for homogeneous refinement (O symmetry) to give a final map with a resolution of 1.47 Å (1.63 Å).

Reconstructions were visualized with Chimera X, using contour levels of 0.077 and 0.24. A molecular model of apoferritin (PDB 6v21) was placed into the map using rigid body fitting.

While the present disclosure describes exemplary embodiments, the detailed description is not intended to limit the scope of the disclosure to the particular forms set forth. The disclosure is intended to cover such alternatives, modifications and equivalents of the described embodiments as may be apparent to one of ordinary skill in the art.

What is claimed is:

1. An apparatus for observing dynamic systems by time-resolved microscopy, the apparatus comprising:
an optical microscope including a cryo stage for receiving a cryo sample and maintaining the cryo sample at a cryogenic temperature;
a heating system configured to temporarily heat at least a portion of the cryo sample such that the portion of the cryo sample melts to a liquid state, temporarily resides in the liquid state, and then revitrifies; and
an image detector associated with the optical microscope for detecting magnified images of the portion of the cryo sample generated by the optical microscope.

2. The apparatus according to claim 1, wherein the heating system includes one or more illumination sources each generating a light beam directed onto the portion of the cryo sample.

3. The apparatus according to claim 2, wherein the optical microscope includes an optical axis intersecting the cryo stage, the one or more illumination sources are spaced apart from the optical axis, and the heating system further includes at least one optical element arranged to direct the light beam from each of the one or more illumination sources along the optical axis onto the portion of the cryo sample.

4. The apparatus according to claim 3, wherein the at least one optical element includes a dichroic filter for reflecting light in a predetermined wavelength band.

5. The apparatus according to claim 2, wherein the one or more illumination sources includes an illumination source generating a continuous light beam, and the heating system further includes a modulator for dividing the continuous light beam into a discontinuous light beam comprising at least one light pulse having a predetermined duration.

6. The apparatus according to claim 2, wherein the one or more illumination sources includes an illumination source generating a discontinuous light beam comprising at least one light pulse having a predetermined duration.

7. A method of controlling an apparatus for observing dynamic systems by time-resolved microscopy, the apparatus comprising an optical microscope including a cryo stage for receiving a cryo sample and maintaining the cryo sample at a cryogenic temperature, one or more illumination sources operable to temporarily heat at least a portion of the cryo sample such that the portion of the cryo sample temporarily melts to a liquid state and revitrifies, and an image detector associated with the optical microscope for detecting magnified images of the portion of the cryo sample generated by the optical microscope, the method comprising:
recording a first image of the portion of the cryo sample;
after recording the first image, energizing the one or more illumination sources to apply an illumination power level to temporarily heat the portion of the cryo sample such that the portion of the cryo sample melts to a liquid state and revitrifies;
after the portion of the cryo sample revitrifies, recording a second image of the portion of the cryo sample;
computing a difference image of the portion of the cryo sample by subtracting the first image from the second image;
analyzing the difference image; and
maintaining or adjusting the illumination power level depending on the step of analyzing the difference image.

8. The method according to claim 7, wherein the step of analyzing the difference image includes classifying the difference image into one of a plurality of different classifications.

9. The method according to claim 8, wherein the plurality of different classifications includes a suitable illumination power classification corresponding to a suitable illumination power level of the one or more illumination sources, an insufficient illumination power classification corresponding to an insufficient power level of the one or more illumination sources, and an excessive illumination power classification corresponding to an excessive power level of the one or more illumination sources.

10. A method of correlative light-electron microscopy comprising:
transferring a cryo sample to an apparatus comprising an optical microscope including a cryo stage for receiving the cryo sample and maintaining the cryo sample at a cryogenic temperature, a heating system including one or more illumination sources, and an image detector associated with the optical microscope for detecting magnified images of the cryo sample generated by the optical microscope;
operating the heating system to temporarily heat at least a portion of the cryo sample such that the portion of the cryo sample temporarily melts to a liquid state and revitrifies;
transferring the cryo sample to an electron microscope; and
investigating the cryo sample using the electron microscope.

11. The method according to claim 10, further comprising:
recording one or more optical micrographs of the cryo sample using the image detector; and
recording one or more electron micrographs of the cryo sample using a camera associated with the electron microscope.
